(19) United States
(12) Patent Application Publication
(10) Pub. No.: US 2013/0234310 A1
(43) Pub. Date: Sep. 12, 2013

(54) FLIP CHIP PACKAGE AND METHOD OF MANUFACTURING THE SAME

(71) Applicant: SAMSUNG ELECTRONICS CO., LTD., Gyeonggi-do (KR)

(72) Inventors: Han-Shin Youn, Hwaseong-si (KR); Kyong-Soon Cho, Gyeonggi-do (KR)

(73) Assignee: SAMSUNG ELECTRONICS CO., LTD., Gyeonggi-do (KR)

(21) Appl. No.: 13/651,752

(22) Filed: Oct. 15, 2012

(30) Foreign Application Priority Data
Mar. 7, 2012 (KR) 10-2012-0023607

(51) Int. Cl. H01L 23/48; H01L 21/60

(52) U.S. Cl. 257/690; 438/108; 257/E23.021; 257/E21.506

(57) ABSTRACT

A flip chip package may include package substrate, a semiconductor chip, conductive bumps, a molding member and a heat sink. The semiconductor chip may be arranged over an upper surface of the package substrate. The conductive bumps may be interposed between a lower surface of the semiconductor chip and the upper surface of the package substrate to electrically connect the semiconductor chip and the package substrate with each other. The molding member may be formed on the upper surface of the package substrate to cover the semiconductor chip. The heat sink may make contact with the semiconductor chip to dissipate a heat in the semiconductor chip. An ultrasonic wave may pass through only one interface between the semiconductor chip and the molding member, so that scattering of the ultrasonic wave may be suppressed.

### CROSS-RELATED APPLICATION

This application claims priority under 35 USC §119 to Korean Patent Application No. 2012-23607, filed on Mar. 7, 2012 in the Korean Intellectual Property Office (KIPO), the contents of which are herein incorporated by reference in its entirety.

### TECHNICAL FIELD

The present inventive concept relates to a flip chip package and a method of manufacturing the same. More particularly, the inventive concept relates to a flip chip package including conductive bumps, and a method of manufacturing the flip chip package.

### DISCUSSION OF RELATED ART

Nondestructive tests may be used to detect a void or crack present in a molding member of a semiconductor package. One of these nondestructive tests uses acoustic microscopes with an ultrasonic wave to obtain internal images of the molding member incorporated in the semiconductor package. When an ultrasonic wave is incident on interface formed between different materials, the incident wave scatters, resulting in blurred images. As a result, when many interfaces are positioned between a source of the ultrasonic wave and the molding, the nondestructive test may provide less accurate results due to scattering of an incident ultrasonic wave, resulting in failure to detect voids or cracks present in the molding member.

### SUMMARY

According to one embodiment, a flip chip package comprises a package substrate, a semiconductor chip, conductive humps positioned between the semiconductor chip and the package substrate, forming a space between the semiconductor chip and the package substrate with each other, a molding member filling the space, and a heat sink attached on the molding and having an opening configured to expose a portion of the semiconductor chip. The flip chip package further comprises external terminals attached to a lower surface of the package substrate.

The flip chip package has an opening having an inner surface substantially aligned with inner surfaces of first and last outermost conductive bumps of the conductive bumps. In an embodiment, the flip chip package may have an opening having an inner surface substantially aligned with outer surfaces of outermost conductive bumps among the conductive bumps. In an embodiment, the flip chip package may have an opening having an inner surface substantially aligned with a side surface of the semiconductor chip.

The flip chip package has the heat sink further attached to an edge of the upper surface of the semiconductor chip. In an embodiment, the heat sink is further attached to a side surface of the semiconductor chip. In an embodiment, the heat sink is further attached both to an edge of the upper surface of the semiconductor chip and to a side surface of the semiconductor chip.

According to an embodiment, the flip chip package has an auxiliary heat sink configured to make contact with the heat sink. The auxiliary heat sink may have a protrusion attached to the upper surface of the semiconductor chip.

According to one embodiment of a method of manufacturing a flip chip package, the method comprises attaching a semiconductor chip to an upper surface of a package substrate using conductive bumps, attaching a heat sink to the semiconductor chip, the heat sink having an opening configured to expose a portion of the upper surface of the semiconductor chip, forming a molding member between the package substrate and the heat sink, and performing a nondestructive test on the molding member by applying an ultrasonic wave to the molding member between the conductive bumps through the opening.

The method of manufacturing a flip chip package, after performing the nondestructive test, further comprises attaching an auxiliary heat sink to the heat sink and to the upper surface of the semiconductor chip. The method further comprises mounting external terminals on a lower surface of the package substrate.

According to an embodiment, a flip chip package comprises a package substrate, a first conductive bump row and a second conductive bump rows attached to the package substrate, a semiconductor chip attached to the first and second conductive bump rows, a ring-type heat sink attached to the semiconductor chip having an outer surface aligned with a side surface of the package substrate and an inner surface aligned with outer surfaces of the first conductive bump row and the second conductive bump row, and a molding configured to fill space between the package substrate and the ring type heat sink and to fill space between the package substrate and the semiconductor chip. The first conductive bump row has a plurality of conductive humps, the number of conductive bumps being greater than that of the first conductive bump row.

According to an embodiment, the flip chip package further comprises at least one conductive bump row between the first conductive bump row and the second conductive bump row.

The first conductive bump row and the second conductive bump row are positioned at a center region under the semiconductor chip. In an embodiment, the first conductive bump row is positioned along an edge under the semiconductor chip and the second conductive hump row is positioned along another edge under the semiconductor chip. A first and a last conductive bumps of the first conductive bump row are positioned under the ring-type heat sink.

According to an embodiment, the flip chip package further comprises external terminals attached to a lower surface of the package substrate.

### BRIEF DESCRIPTION OF THE DRAWINGS

Exemplary embodiments will be more clearly understood from the following detailed description taken in conjunction with the accompanying drawings. FIGS. 1 to 13 represent non-limiting, exemplary embodiments as described herein.

FIG. 1 is a plan view illustrating a flip chip package in accordance with an embodiment of the inventive concept;

FIG. 2 is a cross sectional view taken along line X-X′ of FIG. 1;

FIGS. 3 to 6 are cross-sectional views illustrating a method of manufacturing the flip chip package in FIG. 1;

FIG. 7 is a plan view illustrating a flip chip package in accordance with an embodiment of the inventive concept;

FIG. 8 is a cross sectional view taken along line X-X′ of FIG. 7;

FIG. 9 is a view illustrating a flip chip package in accordance with an embodiment of the inventive concept;

FIG. 10 is a cross sectional view taken along line X-X′ of FIG. 9;

FIG. 11 is a cross-sectional view illustrating a flip chip package in accordance with an embodiment of the inventive concept;

FIG. 12 is a plan view illustrating a flip chip package in accordance with an embodiment of the inventive concept; and

FIG. 13 is a cross sectional view taken along line X-X′ of FIG. 12.

### DETAILED DESCRIPTION OF THE EMBODIMENTS

Various exemplary embodiments will be described more fully hereinafter with reference to the accompanying drawings, in which some exemplary embodiments are shown. The present invention may, however, be embodied in many different forms and should not be construed as limited to the exemplary embodiments set forth herein. Rather, these example embodiments are provided so that this disclosure will be thorough and complete, and will fully convey the scope of the present invention to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular exemplary embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Exemplary embodiments are described herein with reference to cross-sectional illustrations that are schematic illustrations of idealized exemplary embodiments (and intermediate structures). As such, variations from the shapes of the illustrations as a result, for example, of manufacturing techniques and/or tolerances, are to be expected. Thus, exemplary embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, exemplary embodiments will be explained in detail with reference to the accompanying drawings.

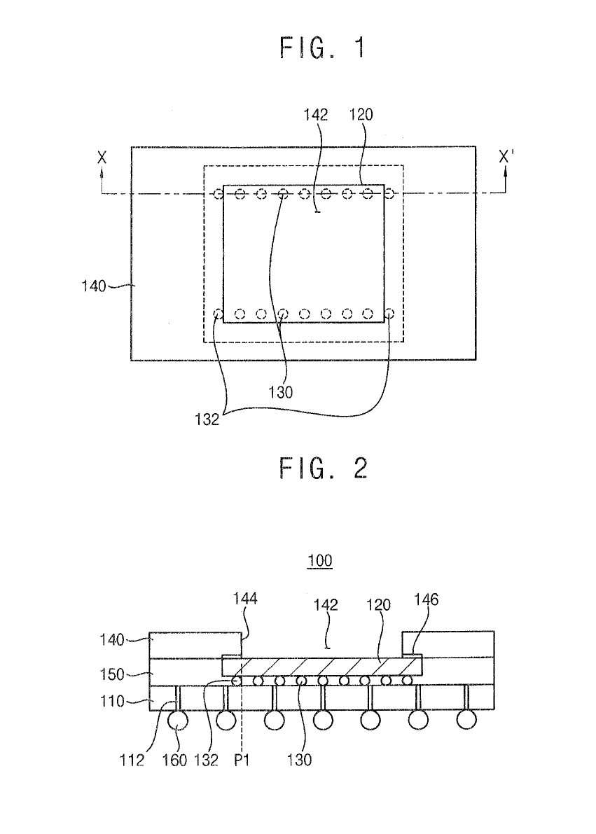

FIG. 1 is a plan view illustrating a flip chip package in accordance with one embodiment of the inventive concept, and FIG. 2 is a cross-sectional view taken along line X-X′ of FIG. 1.

Referring to FIGS. 1 and 2, a flip chip package 100 may include a package substrate 110, a semiconductor chip 120 having an edge pad configuration, conductive bumps 130, a heat sink 140, a molding member 150 and external terminals 160. For an edge pad configuration, a semiconductor chip 220 includes bonding pads (not shown) arranged on a periphery portion of an upper surface of the semiconductor chip 120.

The package substrate 110 may include an insulating substrate (not shown), and a circuit pattern 112 built in the insulating substrate. The circuit pattern 112 may have an upper end exposed through an upper surface of the package substrate 110, and a lower end exposed through a lower surface of the package substrate 110.

The semiconductor chip 120 may be arranged over the upper surface of the package substrate 110. The semiconductor chip 120 may have bonding pads (not shown). In exemplary embodiments, the bonding pads (not shown) may be arranged on an edge of a lower surface of the semiconductor chip 120. Thus, the bonding pads (not shown) may be oriented toward the upper surface of the package substrate 110.

The conductive bumps 130 may include a first conductive bump row and a second conductive bump row 130 and are interposed between the semiconductor chip 120 and the package substrate 110 to electrically connect the semiconductor chip 120 and the package substrate 110 with each other. In exemplary embodiments, each of the conductive bumps 130 may have an upper surface making contact with the bonding pad (not shown), and a lower surface making contact with the circuit pattern 112. Thus, the conductive bumps 130 may have an arrangement substantially the same as that of the bonding pads (not shown). Alternatively, the conductive humps 130 may further include at least one conductive bump row between the first conductive bump row and the second conductive bump row 130. In other words, the conductive bumps 130 may be arranged in a grid array such as a ball-grid array (BOA). Each conductive bump rows may include a series of conductive bumps arranged in a straight line and has the number of conductive bumps 130 larger than that of the conductive bump rows. For example, the flip chip package 100 includes two conductive bump rows 130 and each conductive bump rows include nine conductive bumps.

The heat sink 140 may make contact with the semiconductor chip 120. The heat sink 140 may rapidly dissipate heat generated from the semiconductor chip 120 toward the outside. Thus, the heat sink 140 may be attached to the upper surface of the semiconductor chip 120 using an adhesive 146. In exemplary embodiments, the heat sink 140 may have a lower surface making contact with the upper surface of the semiconductor chip 120. Further, the heat sink 140 may have a size substantially the same as that of the package substrate 110.

In exemplary embodiments, the heat sink 140 may have an opening 142 configured to expose the upper surface of the semiconductor chip 120. The opening 142 may have a square shape. Thus, the heat sink 140 may have a square frame shape. Functions of the opening 142 may be illustrated later.

The molding member 150 may fill a space between the upper surface of the package substrate 110 and the lower surface of the heat sink 140. That is, the molding member 150 may have an inner surface configured to surround side surfaces of the semiconductor chip 120, an upper surface configured to make contact with the lower surface of the heat sink 140, and a lower surface configured to make contact with the upper surface of the package substrate 110. Therefore, the molding member 150 may fill a space between the conductive bumps 130. The molding member 150 may protect the semiconductor chip 120 and the conductive bumps 130 from the external environment. In exemplary embodiments, the molding member 150 may include an epoxy molding compound (EMC).

In exemplary embodiments, the flip chip package 100 may have voids or cracks present in the molding member 150 between the conductive bumps 130. The voids or cracks may occur at a very narrow space between the conductive bumps 130 because the molding member 150 may not fill the narrow space. The voids or the cracks occurred in a manufacturing process may result in reliability concerns under a heat or mechanical stress applied when the flip chip package is assembled and used in a product. Thus, after forming the molding member 150, a nondestructive test for detecting the voids and/or the cracks is necessary to find any cracks or voids of the molding members 150 occurred during a manufacturing process of the flip chip package 100.

The nondestructive test may include a process for applying an ultrasonic wave to the molding member 150 between the conductive bumps 130. Here, the ultrasonic wave may be extremely scattered at an interface between layers having different materials. Therefore, in order to improve reliability of the nondestructive test, it may be required to reduce interfaces between the molding member 130 and an ultrasonic wave irradiator.

In exemplary embodiments, the heat sink 140 may have the opening 142 configured to expose the upper surface of the semiconductor chip 120. Thus, only one interface between the semiconductor chip 120 and the molding member 150 may exist over the molding member 150 between the conductive bumps 130. Therefore, the ultrasonic wave may be scattered at only one interface, so that the scattering of the ultrasonic wave may be greatly decreased.

The voids or the cracks may be mainly generated in the portions of the molding member 150 between the conductive bumps 150. Therefore, the opening 142 may be configured to expose a portion of the semiconductor chip 120 to the extent that the molding member 150 between the conductive bumps 130 is positioned under the opening 142. In exemplary embodiments, the opening 142 may have an inner surface 144. The inner surface 144 of the opening 142 may be substantially aligned along an imaginary vertical plane P1 with an inner surface of an outermost conductive bump 132 among the conductive bumps 130. In other words, a first and a last conductive bumps 132 of the first and second conductive bump rows 130 are positioned under the heat sink 140. That is, the inner surface 144 of the opening 142 may be substantially aligned with the inner surface of the outermost conductive bump 132. Thus, the conductive bumps 130 except for the outermost conductive bumps 132 may be positioned under the opening 142. In other words, the first and the last conductive bumps 132 are positioned under the heat sink 140. The size of the opening 142 may vary in accordance with arrangements of the conductive bumps 130.

The external terminals 160 may be mounted on the lower ends of the circuit pattern 112 exposed through the lower surface of the package substrate 110. In exemplary embodiments, the external terminals 160 may include solder balls.

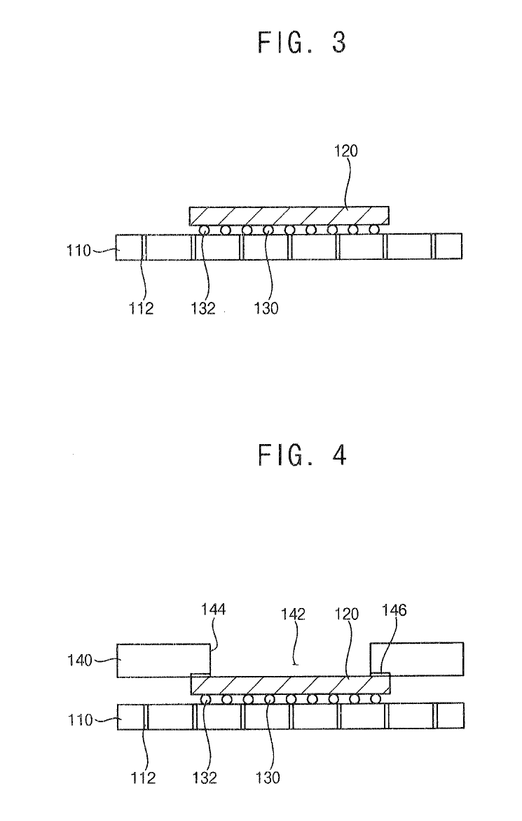

FIGS. 3 to 6 are cross-sectional views taken along line X-X′ illustrating a method of manufacturing the flip chip package of FIG. 1.

Referring to FIG. 3, the bonding pads (now shown) of the semiconductor chip 120 may be electrically connected with the circuit pattern 112 of the package substrate 110 using the conductive bumps 130. In exemplary embodiments, the conductive bumps 130 may be formed by a reflow process.

Referring to FIG. 4, the heat sink 140 having the opening 142 may be attached to the upper surface of the semiconductor chip 120 using an adhesive 146. The inner surface 144 of the opening 142 may be aligned along an imaginary vertical plane P1 with the inner surface of the outermost conductive bump 132, so that spaces between the conductive bumps 130 may be positioned under the opening 142.

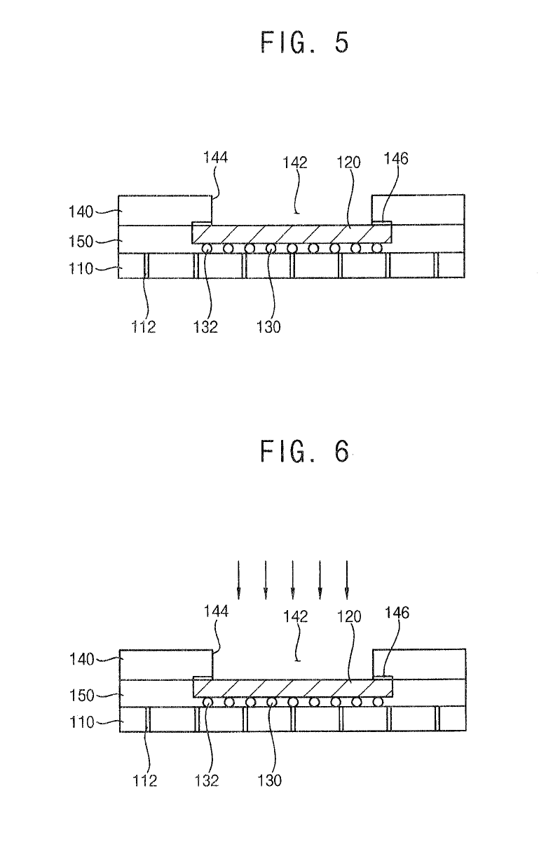

Referring to FIG. 5, a pasted molding material may fill the space between the package substrate 110 and the heat sink 140, forming the molding member 150 configured to surround the side surfaces of the semiconductor chip 120. The molding member 150 may also fill the space between the conductive bumps 130. The molding member 150 may have the upper surface making contact with the lower surface of the heat sink 140, and the lower surface making contact with the upper surface of the package substrate 110.

The solid molding member 150 may have a weak bonding strength with respect to the heat sink 140. In contrast, the pasted molding material may have strong bonding strength with respect to the heat sink 140. Therefore, the molding process may be performed after attaching the heat sink 140 to the semiconductor chip 120, so that the molding member 150 may be firmly attached to the heat sink 140.

Alternatively, after forming the molding member 150 may be formed on the upper surface of the package substrate 110, the heat sink 140 may be attached to the upper surface of the molding member 150 using an adhesive.

Referring to FIG. 6, the nondestructive test using the ultrasonic wave may be performed on the molding member 150 to detect voids and/or cracks in the molding member 150. For the nondestructive test, the ultrasonic wave may be applied to the molding member 150 under the semiconductor chip 120 through the opening 142. Under the test, scattering of the incoming ultrasonic wave may be suppressed because the wave goes through only one interface between the semiconductor chip 120 and the molding member 150. The suppression of the incoming ultrasonic wave may enhance the quality of an ultrasonic image showing internal status of the molding member 150 formed between the conductive bumps 130.

The external terminals 160 may be mounted on the lower ends of the circuit pattern 112 exposed through the lower surface of the package substrate 110 to manufacture the flip chip package 100 in FIG. 1.

According to this exemplary embodiment, the heat sink may have an opening configured to expose the upper surface of the semiconductor chip under a nondestructive test using an ultrasonic wave. The opening may have the inner surface substantially aligned with that of the outermost conductive bump. When the ultrasonic wave is applied to the molding member filled between the conductive bumps through the opening, the ultrasonic wave may pass through only one interface formed between the semiconductor chip and the molding member, so that scattering of the ultrasonic wave may be suppressed. As a result, the nondestructive test on the molding member between the conductive bumps may have improved reliability.

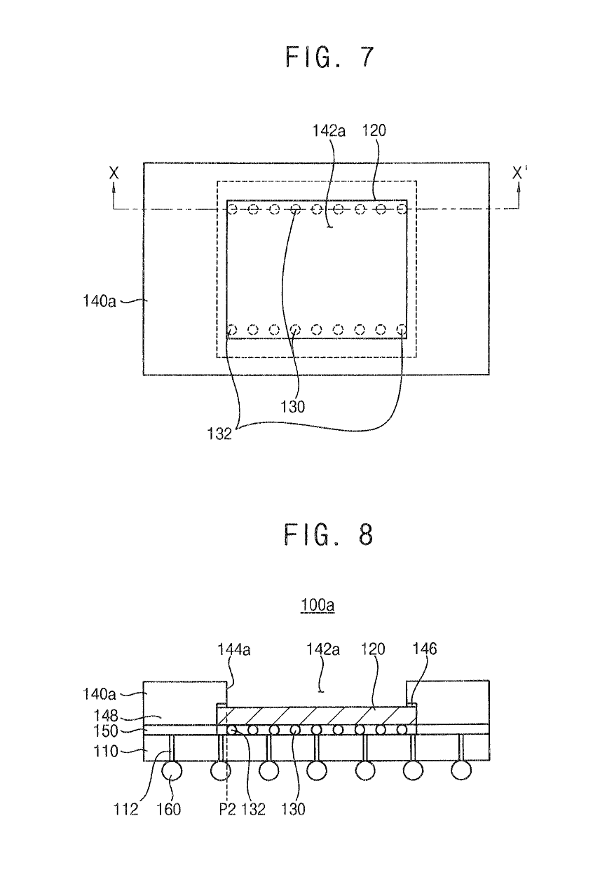

FIG. 7 is a plan view illustrating a flip chip package in accordance with an embodiment of the inventive concept, and FIG. 8 is a cross-sectional view taken along line X-X′ of FIG. 7.

A flip chip package 100a of FIG. 8 may be substantially identical with that of FIG. 1 except for a heat sink arrangement. Like numerals may refer to like elements and any further descriptions with respect to the same element may be omitted from the following descriptions for brevity.

Referring to FIGS. 7 and 8, a heat sink 140a may have an opening 142a. The opening 142a may be configured to expose a portion of the semiconductor chip 120 to the extent that all of the conductive bumps 130 are positioned under the opening. The opening 142a may have an inner surface 144a aligned along an imaginary vertical plane P2 with an outer surface of the outermost conductive bump 132. When the flip chip package 100a is subject to a non-destructive test using a ultrasonic wave, the ultrasonic wave may be accurately applied through the opening 142a to portions of the molding member 150 between an upper surface of the outermost conductive bump 132 and the lower surface of the semiconductor chip 120, and between a lower surface of the outermost conductive bump 132 and the upper surface of the package substrate 110. Thus, voids and/or cracks occurred in the portions of the molding member 150 may be accurately detected.

The heat sink 140a may make contact with the side surfaces of the semiconductor chip 120. In exemplary embodiments, the heat sink 140a includes a contact portion 148 to increase a contact area between the semiconductor chip 120 and the heat sink 140a. The contact portion 148 is formed at the lower portion of the heat sink 140a. The increased contact area may compensate for the loss of contact area resulting from the enlarged opening 142a. Alternatively, the contact portion 148 may be partially formed on the lower surface of the heat sink 140a. For example, the contact portion 148 may be formed on an inner portion of the lower surface of the heat sink 140a adjacent to the side surfaces of the semiconductor chip 120.

A method of manufacturing the flip chip package 100a of FIGS. 7 and 8 may include processes substantially similar to those illustrated with reference to FIGS. 3 to 6. Thus, any further description with respect to the method of manufacturing the flip chip package 100a may be omitted from the following descriptions for brevity.

According to this exemplary embodiment, all of the conductive bumps may be positioned under the opening. Thus, voids and/or cracks occurred in the portions of the molding member between an upper surface of the outermost conductive bump and the lower surface of the semiconductor chip, and between a lower surface of the outermost conductive bump and the upper surface of the package substrate as well as the portions of the molding member between the conductive bumps may be accurately detected.

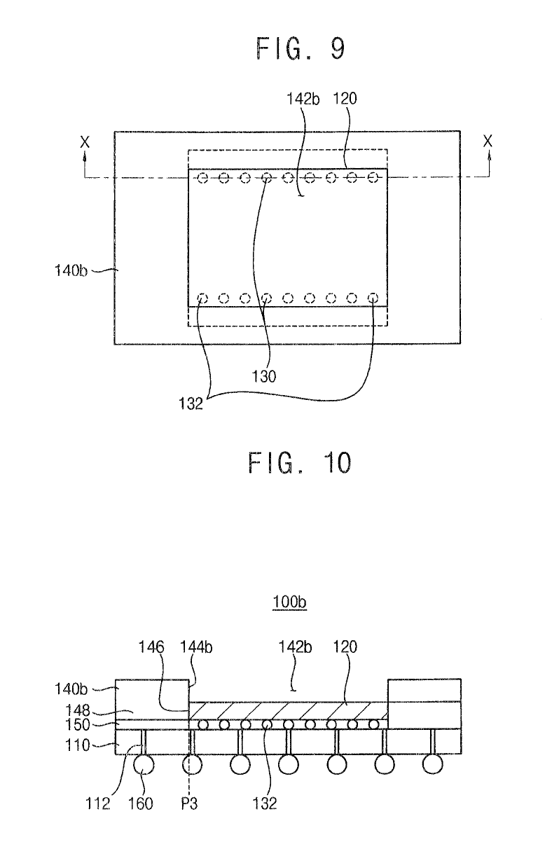

FIG. 9 is a plan view illustrating a flip chip package in accordance with an embodiment of the inventive concept, and FIG. 10 is a cross-sectional view taken along line X-X′ of FIG. 9.

A flip chip package 100b of FIG. 9 may be substantially similar to that of FIG. 1 except for the heat sink arrangement. Like numerals may refer to like elements and any further descriptions with respect to the same elements may be omitted from the following descriptions for brevity.

Referring to FIGS. 9 and 10, a heat sink 140b may have an opening 142b. The opening 142b may have a size for allowing the whole upper surface of the semiconductor chip 120 to be exposed. The opening 142b may have an inner surface 144b aligned along an imaginary vertical plane P3 with a side surface of the semiconductor chip 120. For a nondestructive test, an ultrasonic wave may be applied to the molding member 150 under the semiconductor chip 120 through the opening 142b. Under the test, scattering of the incoming ultrasonic wave may be suppressed because the wave goes through only one interface between the semiconductor chip 120 and the molding member 150. The suppression of the incoming ultrasonic wave may enhance the quality of an ultrasonic image showing internal status of the molding member 150 formed between the conductive bumps 130. Thus, voids and/or cracks occurred in the portion of the molding member 150 under the semiconductor chip 120 may be accurately detected.

The heat sink 140b may not make contact with the upper surface of the semiconductor chip 120 to the extent that the opening 142b has the size for allowing the whole upper surface of the semiconductor chip 120. The heat sink 140b may have a contact portion 148 configured to make contact with the side surfaces of the semiconductor chip 120 instead. In exemplary embodiments, the contact portion 148 may be formed on the whole lower surface of the heat sink 140b. Alternatively, the contact portion 148 may be partially formed on the lower surface of the heat sink 140b. For example, the contact portion 148 may be formed on an inner portion of the lower surface of the heat sink 140b adjacent to the side surfaces of the semiconductor chip 120.

A method of manufacturing the flip chip package 100b may include processes substantially similar to those illustrated with reference to FIGS. 3 to 6. Thus, any further descriptions with respect to the method of manufacturing the flip chip package 100b may be omitted from the following description for brevity.

According to the exemplary embodiments, the upper surface of the semiconductor chip may be wholly exposed through the opening. Thus, voids and/or cracks occurred in the molding member under the semiconductor chip may be accurately detected.

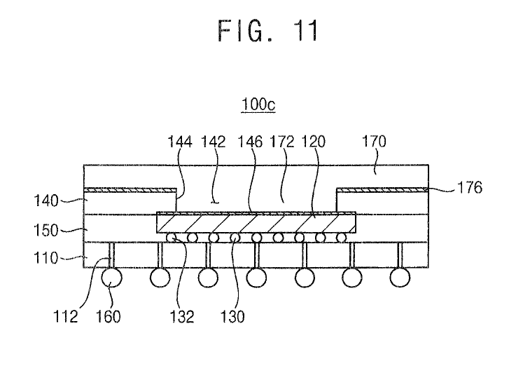

FIG. 11 is a cross-sectional view illustrating a flip chip package in accordance with an embodiment of the inventive concept.

A flip chip package 100c may include elements substantially similar to those of the flip chip package 100 of FIG. 1 except for the heat sink arrangement. Like reference numerals refer to the like elements and any further descriptions with respect to the like element may be omitted from the following descriptions for brevity.

Referring to FIG. 11, the flip chip package 100c may include a heat sink 140 and an auxiliary heat sink 170. In addition to the heat sink 140, the auxiliary heat sink 170 may dissipate heat generated in the semiconductor package 120, thus increasing the heat dissipation area.

The auxiliary heat sink 170 may covers the heat sink 140 and the semiconductor chip 120, filling the opening 142. The protrusion 172 is the lower part of the auxiliary heat sink 170, making contact with the upper surface of the semiconductor chip 120. The protrusion 172 may be formed on a central portion of the lower surface of the auxiliary heat sink 179. The lower surface of the protrusion 172 may make contact with the upper surface of the semiconductor chip 120. Further, the protrusion 172 may have side surfaces configured to make contact with the inner surfaces of the opening 142. That is, the protrusion 172 may have a size substantially the same as that of the opening 142.

The auxiliary heat sink 170 may be attached to the upper surface of the heat sink 140 using a thermal conductive adhesive 176. Further, the auxiliary heat sink 170 may have a size substantially the same as that of the package substrate 110.

The auxiliary heat sink 170 may be attached to the heat sink 140 after a nondestructive test using the ultrasonic wave is performed. Thus, the auxiliary heat sink 170 may have no influence on the reliability of the nondestructive test using the ultrasonic wave.

A method of manufacturing the flip chip package 100c of FIG. 11 may be substantially the same as that illustrated with reference to FIGS. 3 to 6 except for further including attaching the auxiliary heat sink 170 to the heat sink 140. Thus, any further descriptions with respect to the method of manufacturing the flip chip package 100c may be omitted herein for brevity.

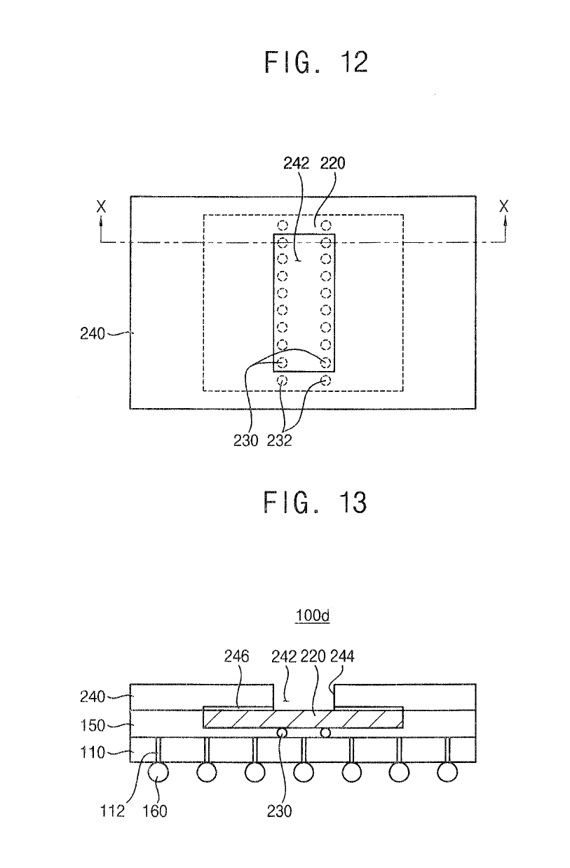

FIG. 12 is a plan view illustrating a flip chip package in accordance with an embodiment of the inventive concept, and FIG. 13 is a cross-sectional view taken along line X-X′ of FIG. 12.

Referring to FIGS. 12 and 13, a flip chip package 100d may include a package substrate 110, a semiconductor chip 220, conductive bumps 230, a heat sink 240, a molding member 150 and external terminals 160. The flip chip package 100d has the identical structure with that of FIG. 2 except that the flip chip package 100d has a semiconductor chip 220 having a center pad configuration (not shown), unlike the edge pad configuration of FIG. 2. For a center pad configuration, a semiconductor chip 220 includes bonding pads (not shown) arranged on a central portion of an upper surface of the semiconductor chip 220.

Thus, any further descriptions with respect to the package substrate 110, the molding member 150 and the external terminals 160 may be omitted herein for brevity.

The conductive bumps 230 may be arranged at a central portion of the flip chip package 100d, being formed between the semiconductor chip 220 and the package substrate 110.

The heat sink 240 may have an opening 242 at a center region, so that the conductive bumps 230 are positioned under the opening 242. The opening 242 may have a long rectangular shape extending along the direction that bonding pads (now shown) are arranged on the lower surface of the semiconductor chip 220. The opening 242 may have an inner surface 244.

Alternatively, the flip chip package 100d may have a structure substantially the same as a structure of the flip chip package 100a in FIG. 7, the flip chip package 100b in FIG. 9 or the flip chip package 100c in FIG. 11.

A method of manufacturing the flip chip package 100d of FIG. 12 may be substantially the same as that illustrated with reference to FIGS. 3 to 6. Thus, any further descriptions with respect to the method of manufacturing the flip chip package 100d may be omitted herein for brevity.

According to exemplary embodiments, the ultrasonic wave of a nondestructive test may be applied to a molding member under a semiconductor chip through an opening of a heat sink. Under the test, scattering of the incoming ultrasonic wave may be minimized because the wave goes through only one interface between the semiconductor chip and the molding member. The reduction of the scattering of the incoming ultrasonic wave may enhance the quality of an ultrasonic image showing internal status of the molding member formed between the conductive bumps. As a result, the reliability of the nondestructive test on the molding member between the conductive bumps may be improved.

The foregoing is illustrative of exemplary embodiments in accordance with the inventive concept and is not to be construed as limiting thereof. Those skilled in the art will readily appreciate that many modifications are possible in the e embodiments without materially departing from the novel teachings and advantages of the present invention. Accordingly, all such modifications are intended to be included within the scope of the present invention as defined in the claims. In the claims, means-plus-function clauses are intended to cover the structures described herein as performing the recited function and not only structural equivalents but also equivalent structures. Therefore, it is to be understood that the foregoing is illustrative of various exemplary embodiments and is not to be construed as limited to the specific exemplary embodiments disclosed, and that modifications to the disclosed exemplary embodiments, as well as other exemplary embodiments, are intended to be included within the scope of the appended claims.

What is claimed is:

1. A flip chip package comprising:
a package substrate;
a semiconductor chip;
conductive bumps positioned between the semiconductor chip and the package substrate, forming a space between the semiconductor chip and the package substrate with each other;
a molding member filling the space; and
a heat sink attached on the molding and having an opening configured to expose a portion of the semiconductor chip.

2. The flip chip package of claim 1, wherein the opening has an inner surface substantially aligned with inner surfaces of first and last outermost conductive bumps of the conductive bumps.

3. The flip chip package of claim 1, wherein the opening has an inner surface substantially aligned with outer surfaces of outermost conductive bumps of the conductive bumps.

4. The flip chip package of claim 1, wherein the opening has an inner surface substantially aligned with a side surface of the semiconductor chip.

5. The flip chip package of claim 1, wherein the heat sink is further attached to an edge of the upper surface of the semiconductor chip.

6. The flip chip package of claim 1, wherein the heat sink is further attached to a side surface of the semiconductor chip.

7. The flip chip package of claim 1, wherein the heat sink is further attached both to an edge of the upper surface of the semiconductor chip and to a side surface of the semiconductor chip.

8. The flip chip package of claim 1, further comprising an auxiliary heat sink configured to make contact with the heat sink.

9. The flip chip package of claim 8, wherein the auxiliary heat sink has a protrusion attached to the upper surface of the semiconductor chip.

10. The flip chip package of claim 1, further comprising external terminals attached to a lower surface of the package substrate.

11. A method of manufacturing a flip chip package, the method comprising:
attaching a semiconductor chip to an upper surface of a package substrate using conductive bumps;
attaching a heat sink to the semiconductor chip, the heat sink having an opening configured to expose a portion of the upper surface of the semiconductor chip;
forming a molding member between the package substrate and the heat sink; and
performing a nondestructive test on the molding member by applying an ultrasonic wave to the molding member between the conductive bumps through the opening.

12. The method of claim 11, after performing the nondestructive test, further comprising attaching an auxiliary heat sink to the heat sink and to the upper surface of the semiconductor chip.

13. The method of claim 11, further comprising mounting external terminals on a lower surface of the package substrate.

14. A flip chip package comprising:
a package substrate;
a first conductive bump row and a second conductive bump rows attached to the package substrate;
a semiconductor chip attached to the first and second conductive bump rows;
a ring-type heat sink attached to the semiconductor chip having an outer surface aligned with a side surface of the package substrate and an inner surface aligned with outer surfaces of the first conductive bump row and the second conductive bump row; and
a molding configured to fill space between the package substrate and the ring type heat sink and to fill space between the package substrate and the semiconductor chip.

15. The flip chip package of claim 14, wherein the first conductive bump row has a plurality of conductive bumps, the number of the conductive bumps being greater than that of the first conductive bump row.

16. The flip chip package of claim 15, further comprising at least one conductive bump row between the first conductive bump row and the second conductive bump row.

17. The flip chip package of claim 15, wherein the first conductive bump row and the second conductive bump row are positioned at a center region under the semiconductor chip.

18. The flip chip package of claim 15, wherein the first conductive bump row is positioned along an edge under the semiconductor chip and the second conductive bump row is positioned along another edge under the semiconductor chip.

19. The flip chip package of claim 15, a first and a last conductive bumps of the first conductive bump row are positioned under the ring-type heat sink.

20. The flip chip package of claim 14, further comprising external terminals attached to a lower surface of the package substrate.
